(19) United States
(12) Patent Application Publication
(10) Pub. No.: US 2024/0234371 A1
(43) Pub. Date: Jul. 11, 2024

(54) CHIP PACKAGE STRUCTURE AND MANUFACTURING METHOD THEREOF

(71) Applicant: Unimicron Technology Corp., Taoyuan City (TW)

(72) Inventors: John Hon-Shing Lau, Taoyuan City (TW); Tzyy-Jang Tseng, Taoyuan City (TW)

(73) Assignee: Unimicron Technology Corp., Taoyuan City (TW)

(21) Appl. No.: 18/171,672

(22) Filed: Feb. 21, 2023

Related U.S. Application Data
(60) Provisional application No. 63/437,128, filed on Jan. 5, 2023.

(51) Int. Cl. H01L 25/065; H01L 23/00; H01L 23/538; H01L 25/00

(52) U.S. Cl. CPC H01L 25/0655; H01L 23/538; H01L 24/05; H01L 24/08; H01L 24/11; H01L 24/14; H01L 24/16; H01L 24/80; H01L 24/81; H01L 24/94; H01L 25/50; H01L 2224/05647; H01L 2224/08225; H01L 2224/1132; H01L 2224/1413; H01L 2224/16227; H01L 2224/80357; H01L 2224/80379; H01L 2224/80895; H01L 2224/80896; H01L 2224/81191; H01L 2224/81192; H01L 2224/94; H01L 2924/05442

(57) ABSTRACT

A chip package structure includes a package carrier, a plurality of chips, a bridge and a plurality of solder balls or C4 bumps. The package carrier includes a plurality of carrier pads. The chips are arranged side by side on the package carrier. Each of the chips includes a plurality of first pads and a plurality of second pads. The bridge is located between the chips and the package carrier and includes a plurality of bridge pads. Each of the first pads is hybrid bonded with each of the bridge pads to form a hybrid bonding pad, so that the chips are electrically connected to each other through the bridge. The solder balls are located between the package carrier and the chips. The second pads of each of the chips are electrically connected to the carrier pads of the package carrier through the solder balls.

### CROSS-REFERENCE TO RELATED APPLICATION

This application claims the priority benefit of U.S. provisional application No. 63/437,128, filed on Jan. 5, 2023. The entirety of the above-mentioned patent application is hereby incorporated by reference herein and made a part of this specification.

### BACKGROUND

### Technical Field

The present disclosure relates to a package structure and a manufacturing method thereof, and in particular to a chip package structure and a manufacturing method thereof for chiplet design and heterogeneous integration packaging application.

### Description of Related Art

The key to heterogeneous chiplet integration is the electrical connection between two chips. Currently, Intel uses the manner of Embedded Multi-Die Interconnect Bridge (EMIB) to connect two chips to achieve partial or local high-density interconnection. However, the problem encountered by the above technology is that the bridge must be embedded in the organic substrate through lamination technology, so the surface needs to be flat enough for subsequent flip-chip packaging. In addition, in the Direct Bonded Heterogeneous Integration of International Business Machines Corporation (IBM), the interconnect between the chiplets and the bridge is through the micro-bumps (such as C2 (chip connection or Cu— pillar with solder cap) bumps). Thus, the flip chip assembly of the package is very complicate and has poor yield. Also, package substrate with cavity is needed.

### SUMMARY

The present disclosure provides a chip package structure, which is bumpless between the chiplets and the bridge, and thus has a lower profile.

The present disclosure also provides a method for manufacturing a chip package structure, which is used to manufacture the above chip package structure, which has a higher density, simpler package substrate, lower cost and better electrical performance.

The chip package structure of the present disclosure includes a package carrier, a plurality of chips, a bridge and a plurality of solder balls. The package carrier includes a plurality of carrier pads. The chips are arranged side by side on the package carrier. Each chip includes a plurality of first pads and a plurality of second pads. The bridge is located between the chips and the package carrier, and the bridge includes a plurality of bridge pads. Each first pad is hybrid bonded with each bridge pad to form a hybrid bonding pad, so that the chips are electrically connected to each other through the bridge. The solder balls are located between the package carrier and the chips. The second pads of each chip are electrically connected with the carrier pads of the package carrier through the solder balls.

In an embodiment of the present disclosure, the material of each first pad and the material of each bridge pad are respectively metal materials.

In an embodiment of the present disclosure, the solder balls are disposed on the carrier pads of the package carrier.

In an embodiment of the present disclosure, the solder balls are disposed on the second pads of each chip.

In an embodiment of the present disclosure, the thickness of the bridge is greater than 20 and less than 50 microns.

The manufacturing method of the chip package structure of the present disclosure includes the following steps. A wafer is provided, and the wafer includes a plurality of chips, wherein each chip includes a plurality of first pads and a plurality of second pads. A plurality of bridges is provided, wherein each bridge includes a plurality of bridge pads. The wafer is bonded with the bridges, wherein each first pad is hybrid bonded with each bridge pad to form a hybrid bonding pad, so that the chips are electrically connected to each other through the bridges. The wafer and the bridges bonded with each other are singulated to form at least one chip unit. A package carrier is provided, and the package carrier includes a plurality of carrier pads. The package carrier is bonded with at least one chip unit, wherein the second pads of each chip are electrically connected with the carrier pads of the package carrier through a plurality of solder balls or C4 (controlled collapse chip connection) bumps.

In an embodiment of the present disclosure, before bonding the package carrier and at least one chip unit, the plurality of solder balls is formed on the carrier pads of the package carrier by stencil printing.

In an embodiment of the present disclosure, after bonding the wafer and the bridge, and before singulating the wafer and the bridges bonded with each other, the solder balls are formed on the second pads of each chip.

In an embodiment of the present disclosure, the material of each first pad and the material of each bridge pad are respectively metal materials.

In an embodiment of the present disclosure, the thickness of the bridges is greater than 20 and less than 50 microns.

Based on the above, in the design of the chip package structure of the present disclosure, the first pad of the chip is hybrid bonded with the bridge pad of the bridge to form a hybrid bonding pad, so that the chips are electrically connected to each other through the bridge. That is, there is bumpless between the chips and the bridge, so the chip package structure of the present disclosure can have a lower profile. In addition, the manufacturing method of the chip package structure of the present disclosure has a very high density, lower cost and better electrical performance because there is bumpless between the chips and the bridge.

In order to make the above-mentioned features and advantages of the present disclosure more comprehensible, the following specific embodiments are described in detail together with the accompanying drawings.

### BRIEF DESCRIPTION OF THE DRAWINGS

FIG. 1 is a schematic cross-sectional view of a chip package structure according to an embodiment of the present disclosure.

FIG. 2A to FIG. 2D are schematic diagrams of partial steps of a manufacturing method of a chip package structure according to an embodiment of the present disclosure.

FIG. 3A to FIG. 3C are schematic diagrams of partial steps of a manufacturing method of a chip package structure according to another embodiment of the present disclosure.

### DESCRIPTION OF THE EMBODIMENTS

The present disclosure can be understood by referring to the following detailed description in conjunction with the accompanying drawings. It should be noted that, for the sake of easy understanding for readers and the simplicity of the drawings, the elements in the drawings are not drawn according to actual scale. In addition, the quantity and size of each element in the drawings are only for illustration and are not intended to limit the scope of the present disclosure.

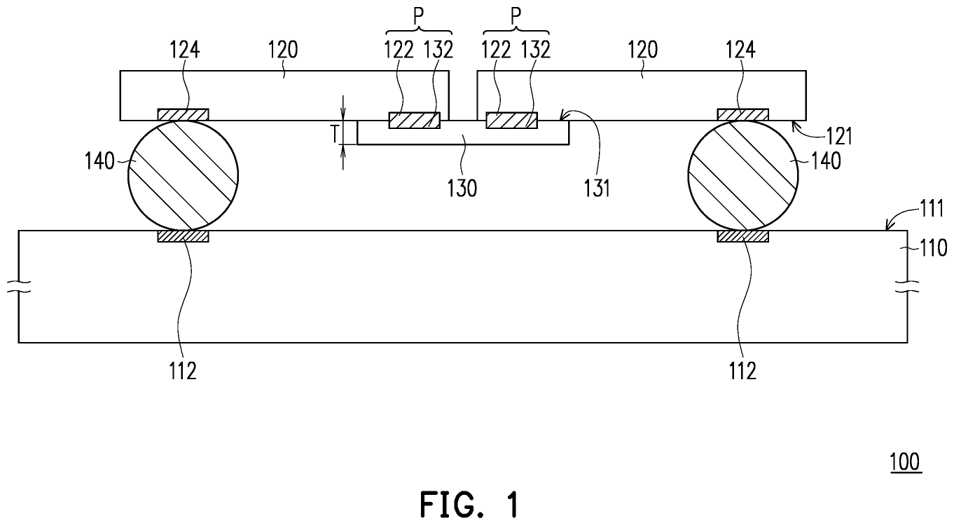

FIG. 1 is a schematic cross-sectional view of a chip package structure according to an embodiment of the present disclosure. Please refer to FIG. 1, in this embodiment, the chip package structure 100 includes a package carrier 110, a plurality of chips 120, a silicon bridge 130 and a plurality of solder balls or C4 bumps 140. The package carrier 110 includes a plurality of carrier pads 112. The chips 120 are arranged side by side on the package carrier 110 at intervals. Each chip 120 includes a plurality of first pads 122 and a plurality of second pads 124. The bridge 130 is located between the chips 120 and the package carrier 110, and the bridge 130 includes a plurality of bridge pads 132. Each first pad 122 is hybrid bonded with each bridge pad 132 to form a hybrid bonding P, so that the chips 120 are electrically connected to each other through bridge 130. Solder balls or C4 bumps 140 are located between the package carrier 110 and the chips 120. The first pad 122 and the bridge pad 132 respectively are bumpless pad. The second pads 124 of each chip 120 are electrically connected to the carrier pads 112 of the package carrier 110 through the solder balls or C4 bumps 140.

Specifically, the package carrier 110 has a surface 111, and the carrier pads 112 are embedded in the surface 111, which means that the carrier pads 112 are flush with the surface 111 but is not limited thereto. In another embodiment, the carrier pads 112 may also be arranged on the surface 111, which means that the carrier pads 112 protrude from the surface 111. The chip 120 has an active surface 121, and the first pads 122 and the second pads 124 are embedded in the active surface 121, which means that the first pads 122 and the second pads 124 are flush with the active surface 121 but is not limited thereto. In another embodiment, the first pads 122 and the second pads 124 may also be disposed on the active surface 121, which means the first pads 122 and the second pads 124 protrude from the active surface 121. Herein, the chip 120 may be, for example, a logic chip, a memory chip, a chiplet or other system-on-chip (SoC), etc., but is not limited thereto. The material of the first pad 122 and the material of the second pad 124 are, for example, metal materials such as copper, but is not limited thereto.

Furthermore, bridge 130 of this embodiment has a surface 131, and the bridge pads 132 are embedded in the surface 131, which means that the bridge pads 132 are flush with the surface 131, but it is not limited thereto. In another embodiment, bridge pads 132 may also be disposed on the surface 131, which means that the bridge pads 132 protrude from the surface 131. Herein, the size of bridge 130 is very small and thin, wherein the thickness T of the bridge 130 is, for example, greater than 20 and less than 50 microns. The material of the bridge pad 132 is, for example, metal, such as copper, but is not limited thereto. As shown in FIG. 1, the surface 131 of the bridge 130 is flush with the active surface 121 of the chip 120. The first pad 122 of the chip 120 is hybrid bonded with the corresponding bridge pad 132 of the bridge 130, the hybrid bonding is metal-to-metal bonding, and a hybrid bonding pad P is formed, so that the chips 120 are electrically connected to each other through the bridge 130. In other words, chip 120 of this embodiment is directly structurally bonded to the bridge 130, and there is bumpless between the chips 120 and the bridge 130, so the chip package structure 100 of this embodiment can have a lower profile, very fine pitch, very high density.

In addition, in this embodiment, the solder ball or C4 bump 140 may be disposed on the carrier pad 112 of the package carrier 110 but is not limited thereto. In another embodiment, the solder ball or C4 bump 140 may also be disposed on the second pad 124 of each chip 120. Herein, the solder ball or C4 bump 140 is, for example, a C4 bump, and the diameter thereof is, for example, 75 microns to 100 microns, but is not limited thereto.

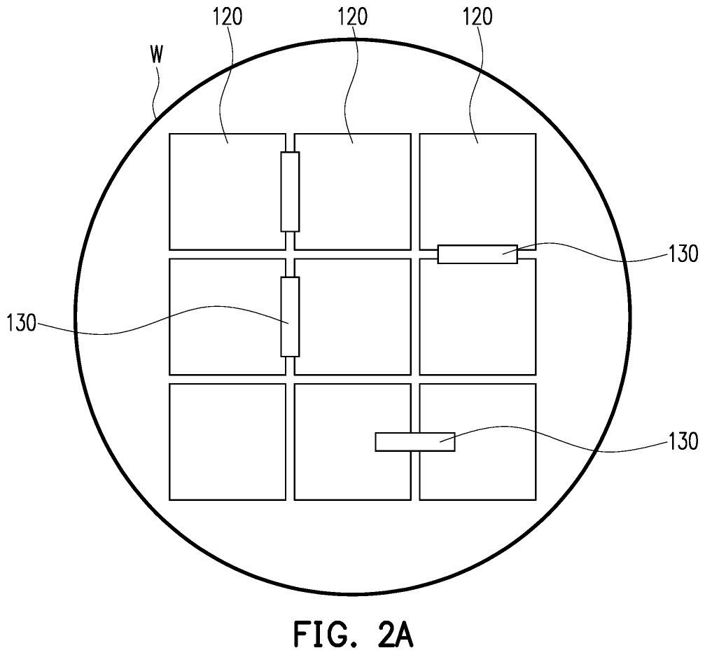

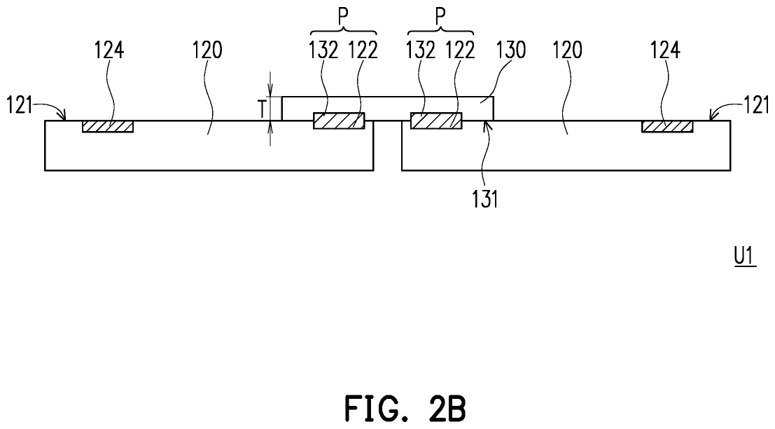

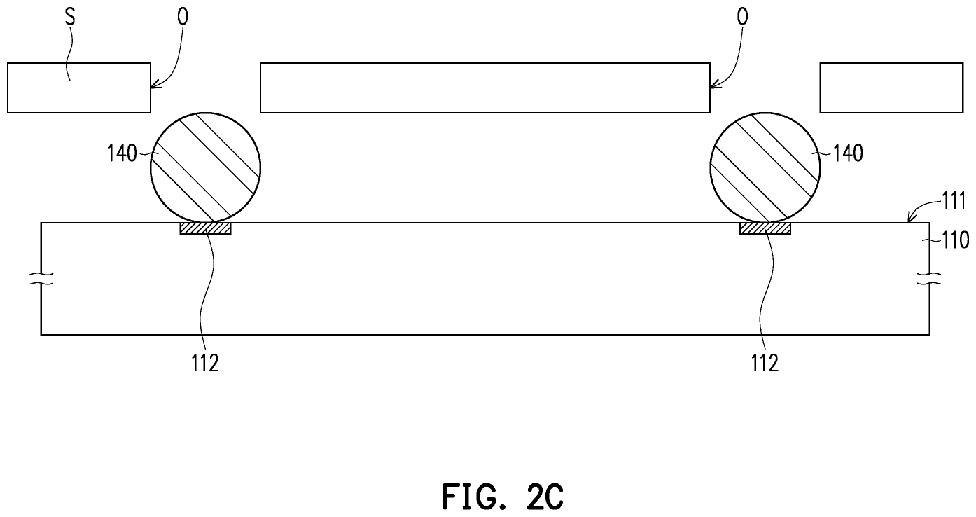

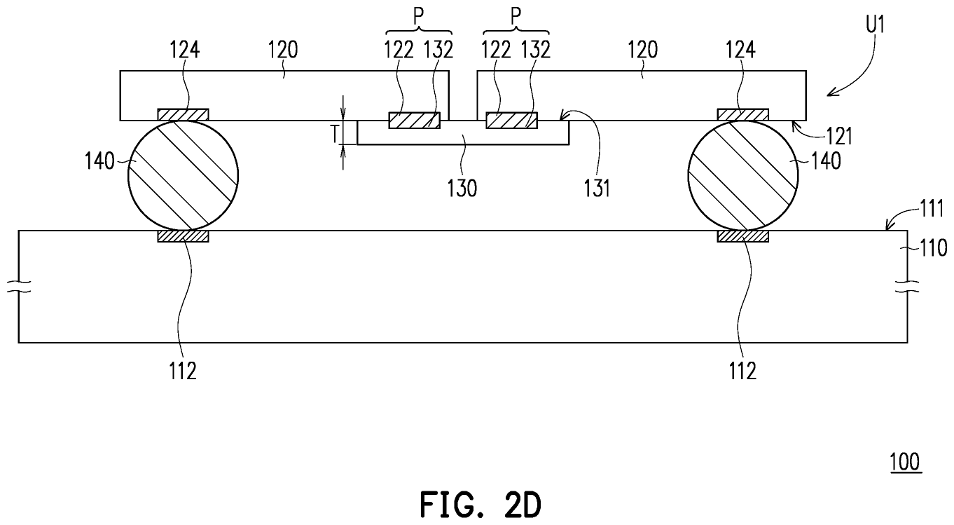

The above only introduces the chip package structure 100 of the present disclosure, but does not introduce the manufacturing method of the chip package structure of the present disclosure. Hereinafter, the chip package structure 100 in FIG. 1 will be taken as an example for illustration, and the manufacturing method of the chip package structure of the present disclosure will be described in detail with reference to FIG. 2A to FIG. 2D.

FIG. 2A to FIG. 2D are schematic diagrams of partial steps of a manufacturing method of a chip package structure according to an embodiment of the present disclosure. It should be noted that, for the sake of clarity, FIG. 2A is a schematic top view, FIG. 2B is a schematic cross-sectional view of a single chip unit, and FIG. 2C to FIG. 2D are schematic cross-sectional views.

Please refer to FIG. 2A and FIG. 2B, according to the manufacturing method of the chip package structure of this embodiment, first, a wafer W is provided, and the wafer W includes a plurality of chips 120, each chip 120 includes a plurality of first pads 122 and a plurality of second pads 124. In one embodiment, chemical vapor deposition (CVD) may be used to form a dielectric material, such as silicon dioxide (SiO₂), on the chip wafer. Then, the dielectric material is planarized by chemical mechanical polishing (CMP) to make recesses for the first pads 122 and the second pads 124. Subsequently, the bonding surface is activated by plasma and hydration process to obtain better hydrophilicity and higher hydroxyl density on the bonding surface, and the preparation of wafer W is completed.

Next, continued on FIG. 2A and FIG. 2B, a plurality of bridges 130 is provided, wherein each bridge 130 includes a plurality of bridge pads 132. These bridges are fabricated from a bridge wafer. In one embodiment, CVD may be used to form a dielectric material, such as silicon dioxide, on the bridging wafer. Next, the dielectric material is planarized by CMP, so as to form the recesses for the bridge pads 132. Then, after coating the wafer surface with a protective layer, the bridging wafer is cut into individual chips (still on the blue tape of the wafer) to keep out any particles and contaminants that could cause interfacial voids during subsequent bonding process. Subsequently, the bonding surface is activated by plasma and hydration process, so as to obtain better hydrophilicity and higher hydroxyl density on the bonding surface, and the preparation of the bridges 130 is completed.

Next, continued on FIG. 2A and FIG. 2B, the wafer W and the bridges 130 are bonded, wherein each first pad 122 is hybrid bonded with each bridge pad 132 to form a hybrid bonding pad P, so that the chips 120 are electrically connected to each other through the bridges 130. In one embodiment, each bridge 130 may be picked-and-placed onto the wafer W, and silicon dioxide (SiO₂) (i.e., dielectric material) to silicon dioxide (SiO₂) bonding is performed at room temperature. Subsequently, an annealing process is performed to achieve covalent bonding between oxide layers, metallic bonding between copper (i.e., first pad 122) and copper (i.e., bridge pad 132) contacts, and diffusion of copper atoms.

Next, continued on FIG. 2A and FIG. 2B, the wafer W and the bridges 130 bonded with each other are singulated (i.e., dicing process) to form at least one chip unit U1 (one is schematically shown in FIG. 2B). As shown in FIG. 2B, the chip unit U1 includes two chips 120 and one bridge 130. Herein, the thickness T of the bridge 130 is, for example, greater than 20 and less than 50 microns.

Next, referring to FIG. 2C, a package carrier 110 is provided, and the package carrier 110 includes a plurality of carrier pads 112. After that, the solder balls or C4 bumps 140 are formed on the carrier pads 112 of the package carrier 110 by stencil printing. The template S has a plurality of openings O, wherein the openings O may correspond to the carrier pads 112 of the package carrier 110 respectively, and the solder paste may be printed onto the surface 111 of the package carrier 110 through the openings O to form the solder balls or C4 bumps 140.

Finally, please refer to FIG. 2D, the package carrier 110 and chip unit U1 are bonded, wherein the second pad 124 of each chip 120 is electrically connected to the carrier pad 112 of the package carrier 110 through the solder ball or C4 bump 140. So far, the fabrication of chip package structure 100 has been completed.

Other embodiments are listed below for illustration. It must be noted here that the following embodiments use the component numerals and part of the content of the previous embodiments, wherein the same numerals are used to denote the same or similar components, and descriptions of the same technical content are omitted. For the description of omitted parts, reference may be made to the foregoing embodiments, and the following embodiments will not be repeated.

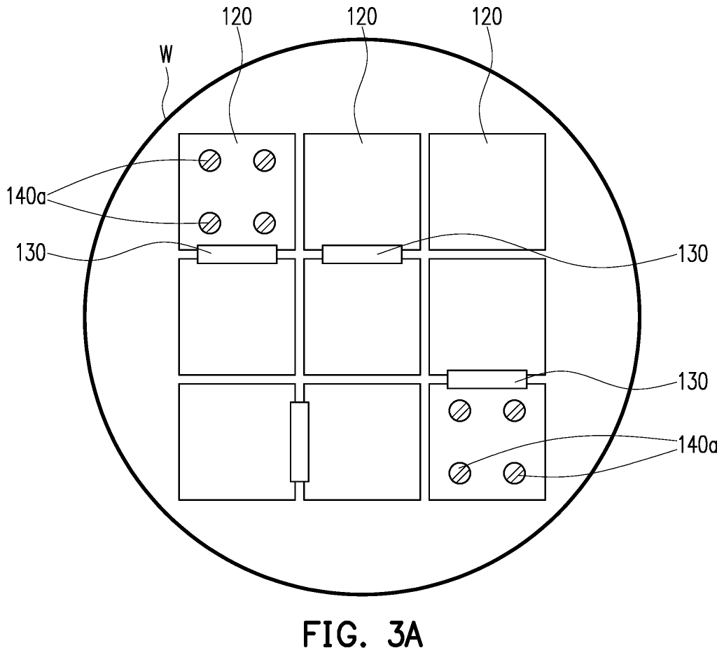

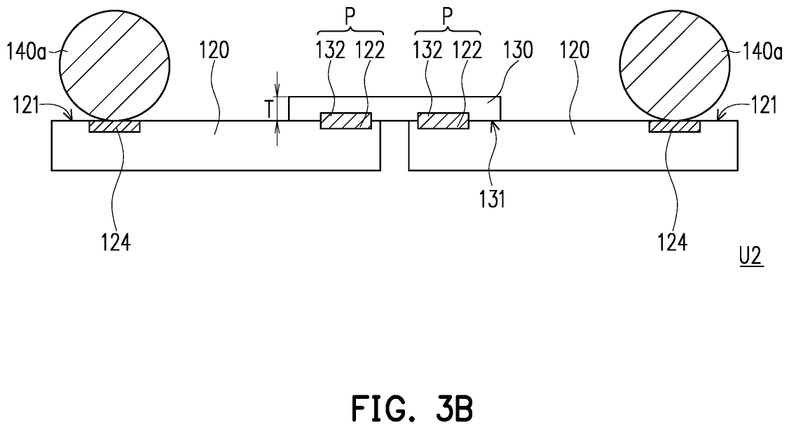

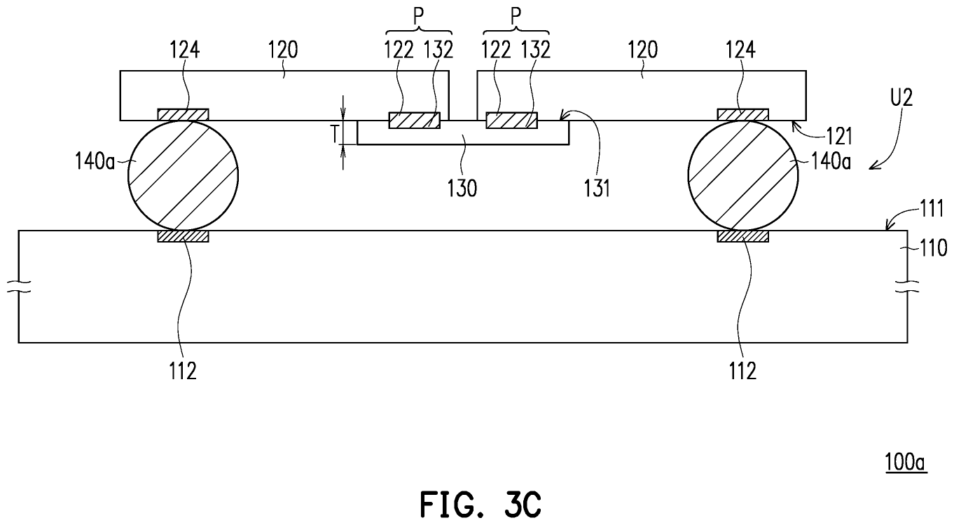

FIG. 3A to FIG. 3C are schematic diagrams of partial steps of a manufacturing method of a chip package structure according to another embodiment of the present disclosure. It should be noted that, for the sake of clarity, FIG. 3A is a schematic top view, FIG. 3B is a schematic cross-sectional view of a single chip unit, and FIG. 3C is a schematic cross-sectional view.

Please refer to FIG. 2A, FIG. 2B, FIG. 3A and FIG. 3B, the manufacturing method of the chip package structure of this embodiment is similar to the manufacturing method of the above-mentioned chip package structure, but the main difference between the two lies on that: in this embodiment, after bonding the wafer W and the bridges 130, a solder ball or C4 bump 140a is formed on the second pad 124 of each chip 120.

Next, please refer to FIG. 3A and FIG. 3B, the wafer W and the bridges 130 bonded with each other are singulated (i.e., dicing process) to form at least one chip unit U2 (one is schematically shown in FIG. 3B). Herein, the chip unit U2 includes two chips 120, one bridge 130 and a plurality of solder balls or C4 bumps 140a.

Afterwards, referring to FIG. 3C, a package carrier 110 is provided, and the package carrier 110 includes a plurality of carrier pads 112. Finally, the package carrier 110 is bonded to the chip unit U2, wherein the second pad 124 of each chip 120 is electrically connected to the carrier pad 112 of the package carrier 110 through the solder ball or C4 bump 140a. So far, the fabrication of the chip package structure 100a has been completed.

To sum up, in the design of the chip package structure of the present disclosure, the first pad of the chip is hybrid bonded with the bridge pad of the bridge to form a hybrid bonding pad, so that the chips are electrically connected to each other through the bridge. That is, there is bumpless between the chips and the bridge, so the chip package structure of the present disclosure can have a lower profile. In addition, the manufacturing method of the chip package structure of the present disclosure has a higher density, lower cost and better electrical performance because there is bumpless between the chips and the bridge.

Although the present disclosure is disclosed with reference to embodiments above, the embodiments are not intended to limit the present disclosure. Any person of ordinary skill in the art may make some variations and modifications without departing from the spirit and scope of the disclosure, and therefore, the protection scope of the present disclosure should be defined in the following claims.

What is claimed is:

1. A chip package structure, comprising:
a package carrier, including a plurality of carrier pads;
a plurality of chips, arranged side by side on the package carrier, wherein each of the plurality of chips includes a plurality of first pads and a plurality of second pads;
a bridge, located between the plurality of chips and the package carrier, wherein the bridge includes a plurality of bridge pads, each of the plurality of first pads is hybrid bonded with each of the plurality of bridge pads to form a hybrid bonding pad, so that the plurality of chips is electrically connected to each other through the bridge; and
a plurality of solder balls or C4 bumps, located between the package carrier and the plurality of chips, wherein the plurality of second pads of each of the plurality of chips is electrically connected with the plurality of carrier pads of the package carrier through the plurality of solder balls or C4 bumps.

2. The chip package structure according to claim 1, wherein the material of each of the plurality of first pads and the material of each of the plurality of bridge pads are respectively metal materials.

3. The chip package structure according to claim 1, wherein the plurality of solder balls or C4 bumps is disposed on the plurality of carrier pads of the package carrier.

4. The chip package structure according to claim 1, wherein the plurality of solder balls or C4 bumps is disposed on the plurality of second pads of each of the plurality of chips.

5. The chip package structure according to claim 1, wherein a thickness of the bridge is greater than 20 and less than 50 microns.

6. The chip package structure according to claim 1, wherein a surface of the bridge is flush with an active surface of each of the plurality of chips.

7. A manufacturing method of the chip package structure, comprising:
providing a wafer, wherein the wafer includes a plurality of chips, each of the plurality of chips includes a plurality of first pads and a plurality of second pads;
providing a plurality of bridges, wherein each of the plurality of bridges includes a plurality of bridge pads;
bonding the wafer and the plurality of bridges, wherein each of the plurality of first pads is hybrid bonded with each of the plurality of bridge pads to form a hybrid bonding pad, so that the plurality of chips is electrically connected to each other through the plurality of bridges;
singulating the wafer and the plurality of bridges bonded with each other to form at least one chip unit;
providing a package carrier, wherein the package carrier includes a plurality of carrier pads; and
bonding the package carrier and the at least one chip unit, wherein the plurality of second pads of each of the plurality of chips is electrically connected with the plurality of carrier pads of the package carrier through a plurality of solder balls or C4 bumps.

8. The manufacturing method according to claim 7, wherein before bonding the package carrier and the at least one chip unit, the plurality of solder balls or C4 bumps is formed on the plurality of carrier pads of the package carrier by stencil printing.

9. The manufacturing method according to claim 7, wherein after bonding the wafer and the bridge, and before singulating the wafer and the plurality of bridges bonded with each other, the plurality of solder balls or C4 bumps is formed on the plurality of second pads of each of the plurality of chips.

10. The manufacturing method according to claim 7, wherein the material of each of the plurality of first pads and the material of each of the plurality of bridge pads are respectively metal materials.

11. The manufacturing method according to claim 7, wherein a thickness of the plurality of bridges is greater than 20 and less than 50 microns.

12. The manufacturing method according to claim 7, wherein a surface of each of the plurality of bridges is flush with an active surface of each of the plurality of chips.
